(19) United States
(12) Patent Application Publication
(10) Pub. No.: US 2014/0028521 A1
(43) Pub. Date: Jan. 30, 2014

(54) TUNER TOPOLOGY FOR WIDE BANDWIDTH

(71) Applicant: RF MICRO DEVICES, INC., Greensboro, NC (US)

(72) Inventors: Ruediger Bauder, Feldkirchen-Westerham (DE); Christian Rye Iversen, Vestbjerg (DK)

(73) Assignee: RF Micro Devices, Inc., Greensboro, NC (US)

(21) Appl. No.: 13/851,657

(22) Filed: Mar. 27, 2013

Related U.S. Application Data
(60) Provisional application No. 61/676,550, filed on Jul. 27, 2012.
(60) Provisional application No. 61/700,128, filed on Sep. 12, 2012.
(60) Provisional application No. 61/791,254, filed on Mar. 15, 2013.

(51) Int. Cl. H03H 7/38; H01Q 1/50

(52) U.S. Cl. CPC H03H 7/38; H01Q 1/50
USPC 343/861; 333/32

(57) ABSTRACT

Adjustable impedance tuning circuitry includes a first impedance matching terminal, a second impedance matching terminal, and a plurality of passive components adapted to match the impedance of the first impedance matching terminal and the second impedance matching terminal. The plurality of passive components includes one or more tunable components adapted to adjust the impedance of the adjustable impedance tuning circuitry to maintain an impedance match between the first impedance matching terminal and the second impedance matching terminal over a variety of operating conditions. Each of the one or more tunable components includes one or more switches adapted to selectively alter the impedance of the tunable component. The one or more switches are integrated onto a single semiconductor die in order to facilitate the performance of the adjustable impedance tuning circuitry over a wide bandwidth.

### RELATED APPLICATIONS

This application claims the benefit of provisional patent application Ser. Nos. 61/676,550, filed Jul. 27, 2012, and 61/700,128, filed Sep. 12, 2012, and 61/791,254, filed Mar. 15, 2013, the disclosures of which are hereby incorporated by reference in their entirety.

### FIELD OF THE DISCLOSURE

The present disclosure relates to tuning circuitry for matching the impedance of an antenna in a mobile terminal.

### BACKGROUND

Modern wireless communications standards continue to use an increasing portion of the wireless spectrum. By using techniques such as carrier aggregation, higher bandwidths and thus data rates can be achieved. Although effective at increasing the data rate of a mobile device, compliance with modern wireless communications standards often complicates the design of the antenna and the surrounding circuitry of the mobile device. In order to maintain the efficiency of a mobile device when transmitting and receiving signals, impedance matching circuitry must be used to match the impedance of the antenna with the impedance of the front end circuitry. The impedance of the antenna in a mobile device may change over time due to the orientation of the mobile device, the surface in contact with the mobile device, nearby electromagnetic fields, user contact with the mobile device, etc. As the operating bandwidth of the mobile device increases, so does the sensitivity of the antenna to changes in impedance. Accordingly, impedance matching circuitry is needed that is capable of maintaining an impedance match between the antenna and the front end circuitry over a wide variety of conditions and across a wide operating bandwidth.

### SUMMARY

Adjustable impedance tuning circuitry includes a first impedance matching port, a second impedance matching port, and a plurality of passive components adapted to match the impedance of the first impedance matching port and the second impedance matching port. The plurality of passive components includes one or more tunable components adapted to adjust the impedance of the adjustable impedance tuning circuitry to maintain an impedance match between the first impedance matching port and the second impedance matching port over a variety of operating conditions. Each of the one or more tunable components includes one or more switches adapted to selectively alter the impedance of the tunable component. The one or more switches are integrated onto a single semiconductor die in order to facilitate the performance of the adjustable impedance tuning circuitry over a wide bandwidth.

According to one embodiment, the one or more switches within the one or more tunable components are integrated onto a single semiconductor die using a complementary metal oxide semiconductor (CMOS) process.

According to an additional embodiment, the one or more tunable components including the one or more switches are integrated onto a single semiconductor die in order to facilitate the performance of the adjustable impedance tuning circuitry over a wide bandwidth.

According to an additional embodiment, control circuitry adapted to adjust the state of the one or more switches within the one or more tunable components is integrated onto the same semiconductor die as the one or more switches in order to facilitate the performance of the adjustable impedance tuning circuitry over a wide bandwidth.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 shows a block diagram of a mobile terminal front end according to the present disclosure.

FIG. 2 shows a schematic representation of adjustable impedance tuning circuitry according to one embodiment of the present disclosure.

FIG. 3 shows a schematic representation of adjustable impedance tuning circuitry according to an additional embodiment of the present disclosure.

FIG. 4 shows a schematic representation illustrating details of the layout of the adjustable impedance tuning circuitry shown in FIG. 3 according to one embodiment of the present disclosure.

FIG. 5 shows a cross-sectional view of the adjustable impedance tuning circuitry shown in FIG. 4.

FIG. 6 shows a schematic representation illustrating details of the layout of the adjustable impedance tuning circuitry shown in FIG. 3 according to an additional embodiment of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

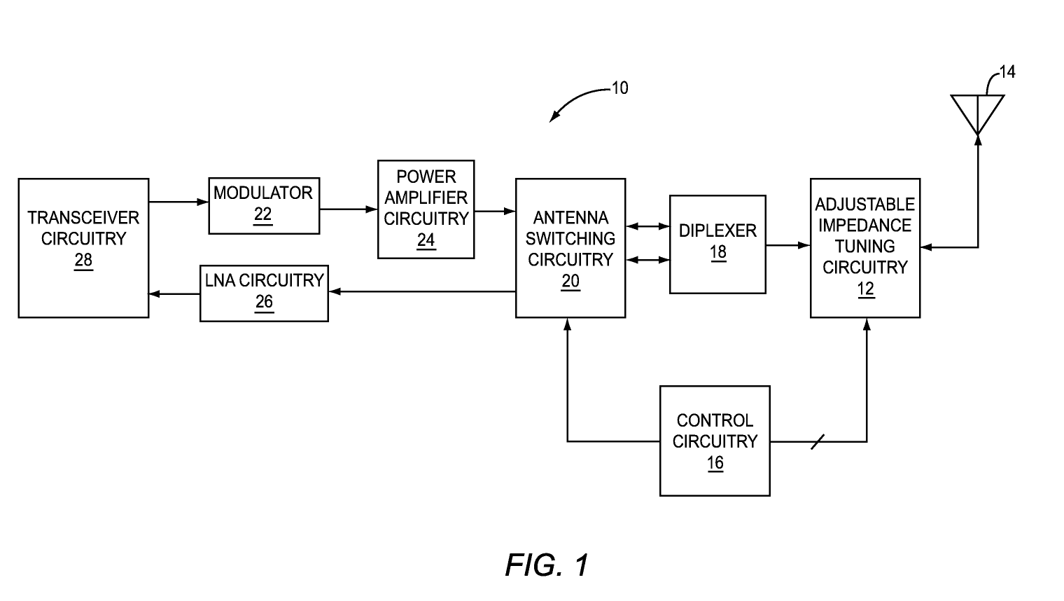

Turning now to FIG. 1, a block diagram of a mobile terminal front end 10 is shown according to one embodiment of the present disclosure. The mobile terminal front end 10 includes adjustable impedance tuning circuitry 12, an antenna 14, control circuitry 16, a diplexer 18, antenna switching circuitry 20, a modulator 22, power amplifier circuitry 24, low-noise amplifier (LNA) circuitry 26, and transceiver circuitry 28 arranged as shown. During a transmit mode of operation, the transceiver circuitry 28 produces baseband signals corresponding with a desired transmit signal. The baseband signals are delivered to the modulator 22, which modulates the baseband signals at a carrier frequency in order to produce a carrier signal. The power amplifier circuitry 24 amplifies the carrier signal to a level appropriate for transmission, and delivers the amplified carrier signal to the antenna switching circuitry 20. The antenna switching circuitry 20 selectively couples one or more output terminals of the power amplifier circuitry 24 with one or more terminals of the diplexer 18 in order to deliver the amplified carrier signal to the diplexer 18. The diplexer 18 combines one or more components of the amplified carrier signal into a single signal for delivery to the adjustable impedance tuning circuitry 12. The adjustable impedance tuning circuitry 12 maintains an impedance match between the diplexer 18 and the antenna 14 over a variety of operating conditions. Accordingly, the amplified carrier signal is able to pass to the antenna 14 with minimal reflection, thereby maximizing the performance of the mobile terminal front end 10.

According to one embodiment of the present disclosure, the control circuitry 16 is coupled to the antenna switching circuitry 20 and the adjustable impedance tuning circuitry 12. The control circuitry 16 may adjust the state of one or more switches in the antenna switching circuitry 20 in order to selectively couple one or more terminals of the power amplifier circuitry 24 and the low-noise amplifier circuitry 26 to one or more terminals of the diplexer 18. The control circuitry 16 may also adjust the impedance of one or more tunable components within the adjustable impedance tuning circuitry 12 in order to match the impedance seen at the diplexer 18 with the impedance seen at the antenna 14, as will be discussed in further detail below.

In a receive mode of operation, information bearing radio frequency signals is received at the antenna 14. The radio frequency signals are passed through the adjustable impedance tuning circuitry 12 to the diplexer 18. The adjustable impedance tuning circuitry 12 maintains an impedance match between the diplexer 18 and the antenna 14. Accordingly, the radio frequency signals are delivered to the diplexer 18 with minimal reflection, thereby maximizing the performance of the mobile terminal front end 10. The diplexer 18 separates the radio frequency signals into one or more high frequency and low frequency components for delivery to the antenna switching circuitry 20. The antenna switching circuitry 20 selectively couples one or more terminals of the diplexer 18 to one or more terminals of the power amplifier circuitry 24 and the low-noise amplifier circuitry 26 in order to deliver the radio frequency signals to the appropriate low noise amplifier. The low-noise amplifier circuitry 26 receives the radio frequency signals and amplifies them for delivery to the transceiver circuitry 28. The transceiver circuitry 28 receives and down-converts the radio frequency signals to baseband signals appropriate for further processing by a mobile terminal.

According to one embodiment, a diplexer does not exist between the antenna 14 and the antenna switching circuitry 20. In this case, the adjustable impedance tuning circuitry 12 may be coupled directly to the antenna switching circuitry 20. Further, the antenna switching circuitry 20 may be broadband to accommodate a large range of signal frequencies.

According to one embodiment, directional couplers (not shown) are included between the antenna 14 and the antenna switching circuitry 20 for directing the flow of signals to and from the antenna 14. For example, a directional coupler may exist between the adjustable impedance tuning circuitry 12 and the antenna 14, between the diplexer 18 and the adjustable impedance tuning circuitry 12, or between each signal path connecting the antenna switching circuitry 20 to the diplexer 18.

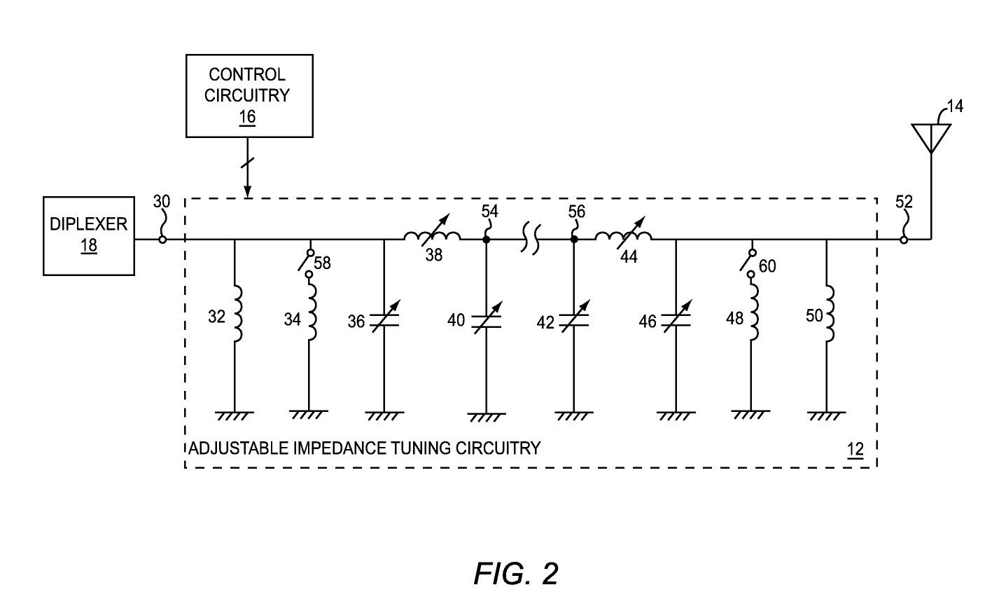

FIG. 2 shows a detailed schematic representation of the adjustable impedance tuning circuitry 12 shown in FIG. 1 according to one embodiment of the present disclosure. The adjustable impedance tuning circuitry 12 includes a first impedance matching terminal 30, a first shunt electrostatic discharge (ESD) inductor 32, a first shunt tuning inductor 34, a first shunt tuning capacitor 36, a first series tuning inductor 38, a second shunt tuning capacitor 40, a third shunt tuning capacitor 42, a second series tuning inductor 44, a fourth shunt tuning capacitor 46, a second shunt tuning inductor 48, a second shunt ESD inductor 50, and a second impedance matching terminal 52 arranged as shown. For context, the antenna 14, the control circuitry 16, and the diplexer 18 are also shown.

The first shunt ESD inductor 32, the first shunt tuning inductor 34, and the first shunt tuning capacitor 36 are coupled between the first impedance matching terminal 30 and ground. The first series tuning inductor 38 is coupled between the first impedance matching terminal 30 and a third terminal 54. The second shunt tuning capacitor 40 is coupled between the third terminal 54 and ground. The third shunt tuning capacitor 42 is coupled between a fourth terminal 56 and ground. The second series tuning inductor 44 is coupled between the fourth terminal 56 and the second impedance matching terminal 52. According to one embodiment, the third terminal 54 and the fourth terminal 56 are coupled together. According to an additional embodiment, further circuitry exists between the third terminal 54 and the fourth terminal 56. The fourth shunt tuning capacitor 46, the second shunt tuning inductor 48, and the second shunt ESD inductor 50 are coupled between the second impedance matching terminal 52 and ground.

The first shunt ESD inductor 32 and the second shunt ESD inductor 50 are adapted to divert ESD signals away from the adjustable impedance tuning circuitry 12 to ground in order to prevent damage to the circuitry as a result of ESD signals. Additionally, the first shunt ESD inductor 32 and the second shunt ESD inductor 50 are adapted to provide a fixed tuning offset in order to maintain an impedance match between the first impedance matching terminal 30 and the second impedance matching terminal 52. The values of the first shunt ESD inductor 32 and the second shunt ESD inductor 50 are chosen such that each one of the shunt ESD inductors 32, 50 is able to effectively protect the adjustable impedance tuning circuitry 12 from ESD signals, while also providing a desirable impedance tuning offset. Accordingly, the first shunt ESD inductor 32 and the second shunt ESD inductor 50 serve multiple functions in the adjustable impedance tuning circuitry 12, thereby increasing the performance of the adjustable impedance tuning circuitry 12 and saving valuable real estate.

The first shunt tuning inductor 34 and the second shunt tuning inductor 48 are adapted to selectively form a reactive divider in order to match an impedance between the first impedance matching terminal 30 and the second impedance matching terminal 52. The first shunt tuning inductor 34 is coupled in series to a first shunt inductor switch 58. The first shunt inductor switch 58 is adapted to selectively couple the first shunt tuning inductor 34 to the first impedance matching terminal 30. When coupled to the first impedance matching terminal 30, the first shunt tuning inductor 34 transforms a high impedance present at the second impedance matching terminal 52 into a lower impedance at the first impedance matching terminal in order to facilitate an impedance match between the first impedance matching terminal 30 and the second impedance matching terminal 52.

The second shunt tuning inductor 48 is coupled in series to a second shunt inductor switch 60. The second shunt inductor switch 60 is adapted to selectively couple the second shunt tuning inductor 48 to the second impedance matching terminal 52. When coupled to the second impedance matching terminal 52, the second shunt tuning inductor 48 transforms a low impedance at the second impedance matching terminal 52 into a higher impedance at the first impedance matching terminal 30 in order to facilitate an impedance match between the first impedance matching terminal 30 and the second impedance matching terminal 52.

The first shunt tuning capacitor 36, the first series tuning inductor 38, and the second shunt tuning capacitor 40 form a “pi” low pass filter, which forms the base for the adjustable impedance tuning circuitry 12. One or more “pi” low pass filters may be combined in series at the center of the adjustable impedance tuning circuitry 12 in order to form the base of the adjustable impedance tuning circuitry 12. FIG. 2 shows two “pi” low pass filters combined in series at the center of the adjustable impedance tuning circuitry 12, the first including the first shunt tuning capacitor 36, the first series tuning inductor 38, and the second shunt tuning capacitor 40, and the second including the third shunt tuning capacitor 42, the second series tuning inductor 44, and the fourth shunt tuning capacitor 46. Although FIG. 2 shows two “pi” low pass filters combined in series to form the base of the adjustable impedance tuning circuitry 12, any number of “pi” low pass filters may be used to form the base of the adjustable impedance tuning circuitry 12 without departing from the principles of the present disclosure.

By adjusting the impedance of the first shunt tuning capacitor 36, the first series tuning inductor 38, the second shunt tuning capacitor 40, the third shunt tuning capacitor 42, the second series tuning inductor 44, and the fourth shunt tuning capacitor 46, either together or independently, an impedance at the first impedance matching terminal 30 can be matched with an impedance at the second impedance matching terminal 52 over a wide variety of operating conditions. Accordingly, the adjustable impedance tuning circuitry 12 is capable of stable operation over a wide bandwidth.

The control circuitry 16 may be coupled to the adjustable impedance tuning circuitry 12 in order to adjust the impedance of the first shunt tuning inductor 34, the first shunt tuning capacitor 36, the first series tuning inductor 38, the second shunt tuning capacitor 40, the third shunt tuning capacitor 42, the second series tuning inductor 44, and the fourth shunt tuning capacitor 46 such that an impedance match is maintained between the first impedance matching terminal 30 and the second impedance matching terminal 52, as will be discussed in further detail below.

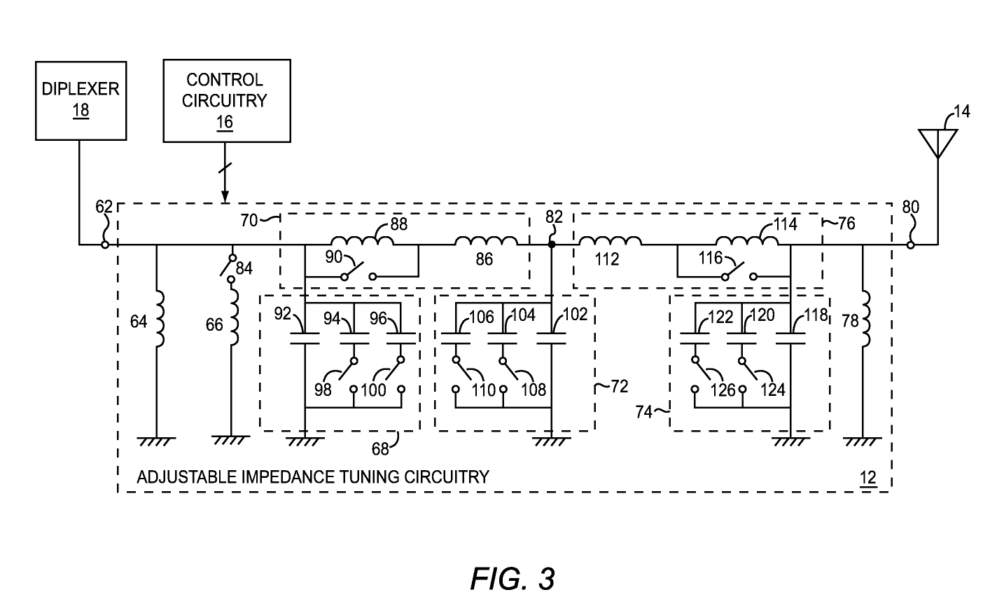

FIG. 3 is a schematic representation of the adjustable impedance tuning circuitry 12 shown in FIG. 1 according to an additional embodiment of the present disclosure. The adjustable impedance tuning circuitry 12 includes a first impedance matching terminal 62, a first shunt ESD inductor 64, a first shunt tuning inductor 66, a first shunt tuning capacitor 68, a first series tuning inductor 70, a second shunt tuning capacitor 72, a third shunt tuning capacitor 74, a second series tuning inductor 76, a second shunt ESD inductor 78, and a second impedance matching terminal 80. For context, the antenna 14, the control circuitry 16, and the diplexer 18 are also shown. The first shunt ESD inductor 64, the first shunt tuning inductor 66, and the first shunt tuning capacitor 68 are coupled between the first impedance matching terminal 62 and ground. The first series tuning inductor 70 is coupled between the first impedance matching terminal 62 and a third terminal 82. The second shunt tuning capacitor 72 is coupled between the third terminal 82 and ground. The second series tuning inductor 76 is coupled between the third terminal 82 and the second impedance matching terminal 80. The third shunt tuning capacitor 74 and the second shunt ESD inductor 78 are coupled between the second impedance matching terminal 80 and ground.

The first shunt ESD inductor 64 and the second shunt ESD inductor 78 are adapted to divert ESD signals away from the adjustable impedance tuning circuitry 12 to ground in order to prevent damage to the circuitry as a result of ESD signals. Additionally, the first shunt ESD inductor 64 and the second shunt ESD inductor 78 are adapted to provide a fixed tuning offset in order to maintain an impedance match between the first impedance matching terminal 62 and the second impedance matching terminal 80. The values of the first shunt ESD inductor 64 and the second shunt ESD inductor 78 are chosen such that each one of the shunt ESD inductors 64, 78 is able to effectively protect the adjustable impedance tuning circuitry 12 from ESD signals, while also providing a desirable fixed tuning offset. Accordingly, the first shunt ESD inductor 64 and the second shunt ESD inductor 78 serve multiple functions in the adjustable impedance tuning circuitry 12, thereby increasing the performance of the adjustable impedance tuning circuitry 12 and saving valuable real estate.

The first shunt tuning inductor 66 is adapted to selectively form a reactive divider in order to match an impedance between the first impedance matching terminal 62 and the second impedance matching terminal 80. The first shunt tuning inductor 66 is coupled in series to a first shunt inductor switch 84. The first shunt inductor switch 84 is adapted to selectively couple the first shunt tuning inductor 66 to the first impedance matching terminal 62. When coupled to the first impedance matching terminal 62, the first shunt tuning inductor 66 transforms a low impedance present at the first impedance matching terminal 62 into a higher impedance in order to facilitate an impedance match between the first impedance matching terminal 62 and the second impedance matching terminal 80.

The first shunt tuning capacitor 68, the first series tuning inductor 70, and the second shunt tuning capacitor 72 form a “pi” low pass filter, which forms the base of the adjustable impedance tuning circuitry 12. One or more “pi” low pass filters may be combined in series at the center of the adjustable impedance tuning circuitry 12 in order to form the base of the adjustable impedance tuning circuitry 12. According to one embodiment, the adjustable impedance tuning circuitry 12 includes two “pi” low pass filters that share a shunt tuning capacitor at their center. As shown in FIG. 3, the first shunt tuning capacitor 68, the first series tuning inductor 70, the second shunt tuning capacitor 72, the second series tuning inductor 76, and the third shunt tuning capacitor 74 form two “pi” low pass filter circuits that are connected at the second shunt tuning capacitor 72. By adjusting the impedance of the first shunt tuning capacitor 68, the first series tuning inductor 70, the second shunt tuning capacitor 72, the second series tuning inductor 76, and the third shunt tuning capacitor 74, either together or independently, an impedance present at the first impedance matching terminal 62 can be matched to an impedance present at the second impedance matching terminal 80. Accordingly, the adjustable impedance tuning circuitry 12 is capable of stable operation over a wide bandwidth.

According to one embodiment of the present disclosure, the first series tuning inductor 70 comprises a fixed inductor in series with one or more switchable inductors. Each one of the switchable inductors are coupled in parallel with an inductor tuning switch in order to selectively couple the switchable inductor in series with the fixed inductor based upon the state of the inductor tuning switch. For example, the first series tuning inductor 70 may comprise a first fixed inductor 86 in series with a first switchable inductor 88. The first switchable inductor 88 may be placed in parallel with a first inductor tuning switch 90 in order to selectively couple the first switchable inductor 88 in series with the first fixed inductor 86. The state of the first inductor tuning switch 90 may be adjusted such that the first switchable inductor 88 is placed in series with the first fixed inductor 86 when the switch is in an open, or OFF, state, and such that the first switchable inductor 88 is bypassed via a short circuit when the switch is in a closed, or ON, state. By selectively placing the first switchable inductor 88 in series with the first fixed inductor 86, the impedance of the first series tuning inductor 70 may be adjusted. Additionally, by coupling the first switchable inductor 88 to the first fixed inductor 86 in series, insertion losses across the first series tuning inductor 70 are minimized, thereby increasing the performance of the adjustable impedance tuning circuitry 12. Although FIG. 3 shows one fixed inductor and one switchable inductor in the first series tuning inductor 70, the first series tuning inductor 70 may include any number of fixed or switchable inductors without departing from the principles of the present disclosure.

According to one embodiment, the second series tuning inductor 76 similarly comprises a fixed inductor in series with one or more switchable inductors. For example, the second series tuning inductor 76 may comprise a second fixed inductor 112 in series with a second switchable inductor 114. The second switchable inductor 114 may be placed in parallel with a second inductor tuning switch 116 in order to selectively couple the second switchable inductor 114 in series with the second fixed inductor 112. The state of the second inductor tuning switch 116 may be adjusted so that the second switchable inductor 114 is placed in series with the second fixed inductor 112 when the switch is in an open, or OFF, state, and such that the second switchable inductor 114 is bypassed via a short circuit when the switch is in a closed, or ON, state. By selectively placing the second switchable inductor 114 in series with the second fixed inductor 112, the impedance of the second series tuning inductor 76 may be adjusted. Additionally, by coupling the second switchable inductor 114 to the second fixed inductor 112 in series, insertion losses across the second series tuning inductor 76 are minimized, thereby increasing the performance of the adjustable impedance tuning circuitry 12. Although FIG. 3 shows one fixed inductor and one switchable inductor in the second series tuning inductor 76, the second series tuning inductor 76 may include any number of fixed or switchable inductors without departing from the principles of the present disclosure.

Although FIG. 3 shows the first series tuning inductor 70 and the second series tuning inductor 76 as a fixed inductor in series with one or more switchable inductors, the first series tuning inductor 70 and the second series tuning inductor 76 may comprise any tunable inductor element without departing from the principles of the present disclosure.

According to one embodiment of the present disclosure, the first shunt tuning capacitor 68 comprises a first programmable array of capacitors (PAC). The first PAC includes a fixed capacitor coupled in parallel with one or more switchable capacitors. Each one of the switchable capacitors are coupled in series with a capacitor tuning switch in order to selectively couple the switchable capacitor in parallel with the fixed capacitor based upon the state of the capacitor tuning switch. For example, the first shunt tuning capacitor 68 may comprise a first fixed capacitor 92 in parallel with a first switchable capacitor 94 and a second switchable capacitor 96. The first switchable capacitor 94 may be placed in series with a first capacitor tuning switch 98 in order to selectively couple the first switchable capacitor 94 in parallel with the first fixed capacitor 92. The state of the first capacitor tuning switch 98 may be adjusted such that the first switchable capacitor 94 is placed in parallel with the first fixed capacitor 92 when the switch is in a closed, or ON, state, and such that the first switchable capacitor 94 is disconnected from the first fixed capacitor 92 when the switch is in an open, or OFF, state.

Similar to the first switchable capacitor 94, the second switchable capacitor 96 may be placed in series with a second capacitor tuning switch 100 in order to selectively couple the second switchable capacitor 96 in parallel with the first fixed capacitor 92. The state of the second capacitor tuning switch 100 may be adjusted such that the second switchable capacitor 96 is placed in parallel with the first fixed capacitor 92 when the switch is in a closed, or ON, state, and such that the second switchable capacitor 96 is disconnected from the first fixed capacitor 92 when the switch is in an open, or OFF, state. By selectively placing the first switchable capacitor 94 and the second switchable capacitor 96 in parallel with the first fixed capacitor 92, the impedance of the first shunt tuning capacitor 68 may be adjusted. Although FIG. 3 shows one fixed capacitor and two switchable capacitors in the first shunt tuning capacitor 68, the first shunt tuning capacitor 68 may comprise any number of fixed or switchable capacitors without departing from the principles of the present disclosure.

According to one embodiment of the present disclosure, the second shunt tuning capacitor 72 similarly comprises a second PAC. For example, the second shunt tuning capacitor 72 may comprise a second fixed capacitor 102 in parallel with a third switchable capacitor 104 and a fourth switchable capacitor 106. The third switchable capacitor 104 may be placed in series with a third capacitor tuning switch 108 in order to selectively couple the third switchable capacitor 104 in parallel with the second fixed capacitor 102. The state of the third capacitor tuning switch 108 may be adjusted such that the third switchable capacitor 104 is placed in parallel with the second fixed capacitor 102 when the third capacitor tuning switch 108 is in a closed, or ON, state, and such that the third switchable capacitor 104 is disconnected from the second fixed capacitor 102 when the switch is in an open, or OFF, state.

Similar to the third switchable capacitor 104, the fourth switchable capacitor 106 may be placed in series with a fourth capacitor tuning switch 110 in order to selectively couple the fourth switchable capacitor 106 in parallel with the second fixed capacitor 102. The state of the fourth capacitor tuning switch 110 may be adjusted such that the fourth switchable capacitor 106 is placed in parallel with the second fixed capacitor 102 when the switch is in a closed, or ON, state, and such that the fourth switchable capacitor 106 is disconnected from the second fixed capacitor 102 when the switch is in an open, or OFF, state. By selectively placing the third switchable capacitor 104 and the fourth switchable capacitor 106 in parallel with the second fixed capacitor 102, the impedance of the second shunt tuning capacitor 72 may be adjusted. Although FIG. 3 shows one fixed capacitor and two switchable capacitors in the second shunt tuning capacitor 72, the second shunt tuning capacitor 72 may comprise any number of fixed or switchable capacitors without departing from the principles of the present disclosure.

According to one embodiment of the present disclosure, the third shunt tuning capacitor 74 comprises a third PAC. For example, the third shunt tuning capacitor 74 may comprise a third fixed capacitor 118 in parallel with a fifth switchable capacitor 120 and a sixth switchable capacitor 122. The fifth switchable capacitor 120 may be placed in series with a fifth capacitor tuning switch 124 in order to selectively couple the fifth switchable capacitor 120 in parallel with the third fixed capacitor 118. The state of the fifth capacitor tuning switch 124 may be adjusted such that the fifth switchable capacitor 120 is placed in parallel with the third fixed capacitor 118 when the switch is in a closed, or ON, state, and such that the fifth switchable capacitor 120 is disconnected from the third fixed capacitor 118 when the switch is in an open, or OFF, state.

Similar to the fifth switchable capacitor 120, the sixth switchable capacitor 122 may be placed in series with a sixth capacitor tuning switch 126 in order to selectively couple the sixth switchable capacitor 122 in parallel with the third fixed capacitor 118. The state of the sixth capacitor tuning switch 126 may be adjusted such that the sixth switchable capacitor 122 is placed in parallel with the third fixed capacitor 118 when the switch is in a closed, or ON, state, and such that the sixth switchable capacitor 122 is disconnected from the third fixed capacitor 118 when the switch is in an open, or OFF, state. By selectively placing the fifth switchable capacitor 120 and the sixth switchable capacitor 122 in parallel with the third fixed capacitor 118, the impedance of the third shunt tuning capacitor 74 may be adjusted. Although FIG. 3 shows one fixed capacitor and two switchable capacitors in the third shunt tuning capacitor 74, the third shunt tuning capacitor 74 may comprise any number of fixed or switchable capacitors without departing from the principles of the present disclosure.

Although FIG. 3 shows the first shunt tuning capacitor 68, the second shunt tuning capacitor 72, and the third shunt tuning capacitor 74 as a PAC, the first shunt tuning capacitor 68, the second shunt tuning capacitor 72, and the third shunt tuning capacitor 74 may comprise any tunable capacitor element without departing from the principles of the present disclosure.

The control circuitry 16 may be coupled to the adjustable impedance tuning circuitry 12 in order to adjust the impedance of the first shunt tuning inductor 66, the first shunt tuning capacitor 68, the first series tuning inductor 70, the second shunt tuning capacitor 72, the second series tuning inductor 76, and the third shunt tuning capacitor 74 such that an impedance match is maintained between the first impedance matching terminal 62 and the second impedance matching terminal 80, as will be discussed in further detail below.

According to one embodiment of the present disclosure, each one of the switches in the first shunt tuning inductor 66, the first series tuning inductor 70, the first shunt tuning capacitor 68, the second shunt tuning capacitor 72, the second series tuning inductor 76, and the third shunt tuning capacitor 74, respectively, comprises a transistor switching element, such as a bipolar junction transistor (BJT), a field effect transistor (FET), or a metal-oxide semiconductor field effect transistor (MOSFET).

According to one embodiment of the present disclosure, the adjustable impedance tuning circuitry 12 is adapted for stable operation between 698-2700 MHz.

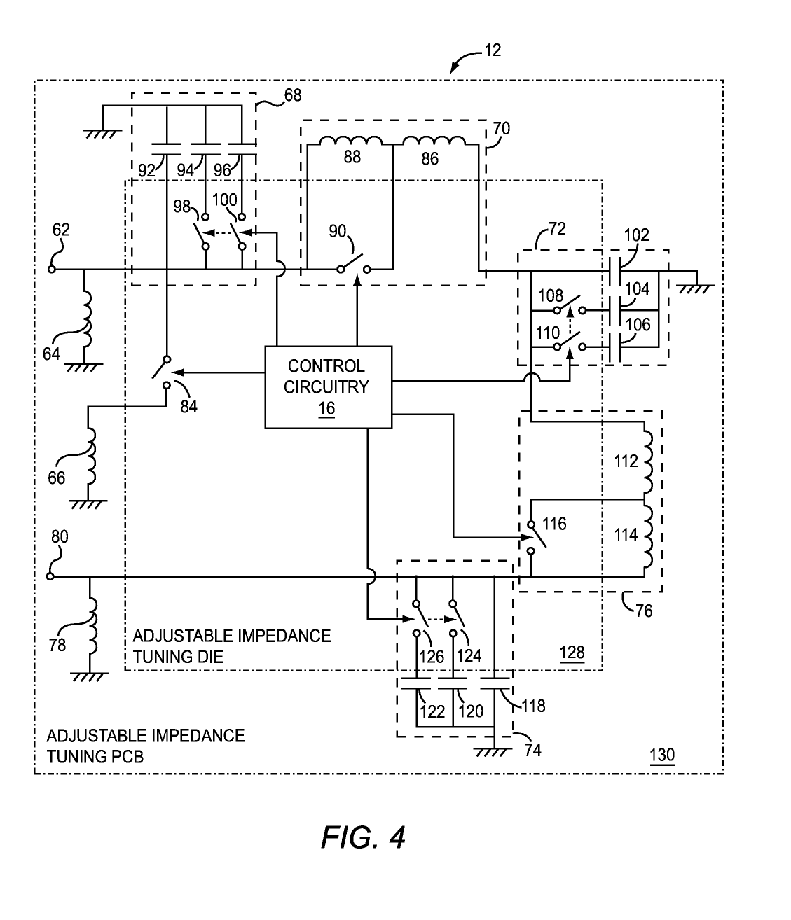

FIG. 4 shows a schematic representation of the adjustable impedance tuning circuitry 12 shown in FIG. 3 including further details of the layout of the adjustable impedance tuning circuitry 12 according to one embodiment of the present disclosure. As shown in FIG. 4, the adjustable impedance tuning circuitry 12 includes an adjustable impedance tuning semiconductor die 128 mounted on top of an adjustable impedance tuning printed circuit board (PCB) 130. As discussed above, each one of the first shunt tuning inductor 66, the first shunt tuning capacitor 68, the first series tuning inductor 70, the second shunt tuning capacitor 72, the second series tuning inductor 76, and the third shunt tuning capacitor 74 are associated with one or more switches adapted to selectively alter their respective impedances. According to one embodiment of the present disclosure, each one of the switches associated with the first shunt tuning inductor 66, the first shunt tuning capacitor 68, the first series tuning inductor 70, the second shunt tuning capacitor 72, the second series tuning inductor 76, and the third shunt tuning capacitor 74 are integrated onto a single semiconductor die, such as the adjustable impedance tuning semiconductor die 128 shown in FIG. 4.

According to this embodiment, only the switches from the first shunt tuning inductor 66, the first shunt tuning capacitor 68, the first series tuning inductor 70, the second shunt tuning capacitor 72, the second series tuning inductor 76, and the third shunt tuning capacitor 74 are integrated onto the adjustable impedance tuning semiconductor die 128. That is, the inductors associated with the first shunt ESD inductor 64, the first shunt tuning inductor 66, the first series tuning inductor 70, the second series tuning inductor 76, and the second shunt ESD inductor 78, as well as the capacitors associated with the first shunt tuning capacitor 68, the second shunt tuning capacitor 72, and the third shunt tuning capacitor 74 are not integrated onto the adjustable impedance tuning semiconductor die 128, and instead are placed on the adjustable impedance tuning PCB 130 on which the adjustable impedance tuning semiconductor die 128 is mounted. By integrating the switches associated with the first shunt tuning inductor 66, the first shunt tuning capacitor 68, the first series tuning inductor 70, the second shunt tuning capacitor 72, the second series tuning inductor 76, and the third shunt tuning capacitor 74 onto the adjustable impedance tuning semiconductor die 128, interference within the adjustable impedance tuning circuitry 12 is reduced, thereby allowing for stable operation of the circuitry over a wide bandwidth. Further, by externally mounting the capacitive and inductive components, the design of the adjustable impedance tuning circuitry 12 remains flexible, and fabrication costs are reduced.

According to one embodiment of the present disclosure, the switches associated with the first shunt tuning inductor 66, the first shunt tuning capacitor 68, the first series tuning inductor 70, the second shunt tuning capacitor 72, the second series tuning inductor 76, and the third shunt tuning capacitor 74 are integrated onto the adjustable impedance tuning semiconductor die 128 using a complementary metal oxide semiconductor (CMOS) process. By using a CMOS process to integrate the switches associated with the first shunt tuning inductor 66, the first shunt tuning capacitor 68, the first series tuning inductor 70, the second shunt tuning capacitor 72, the second series tuning inductor 76, and the third shunt tuning capacitor 74 onto the adjustable impedance tuning semiconductor die 128, the cost of the adjustable impedance tuning circuitry 12 is minimized while maintaining a high level of performance.

According to one embodiment of the present disclosure, the switches associated with the first shunt tuning inductor 66, the first shunt tuning capacitor 68, the first series tuning inductor 70, the second shunt tuning capacitor 72, the second series tuning inductor 76, and the third shunt tuning capacitor 74 are integrated onto the adjustable impedance tuning semiconductor die 128 together with the control circuitry 16, as shown in FIG. 4. By integrating the switches associated with the first shunt tuning inductor 66, the first shunt tuning capacitor 68, the first series tuning inductor 70, the second shunt tuning capacitor 72, the second series tuning inductor 76, and the third shunt tuning capacitor 74 onto the adjustable impedance tuning semiconductor die 128 along with the control circuitry 16, interference within the adjustable impedance tuning circuitry 12 is further reduced, thereby allowing for stable operation of the circuitry over a wide bandwidth.

The control circuitry 16 is coupled to each one of the switches on the adjustable impedance tuning semiconductor die 128, and is adapted to adjust the state of one or more switches in order to match an impedance at the first impedance matching terminal 62 to an impedance at the second impedance matching terminal 80.

According to one embodiment of the present disclosure, the adjustable impedance tuning circuitry 12 is adapted for stable operation between 698-2700 MHz.

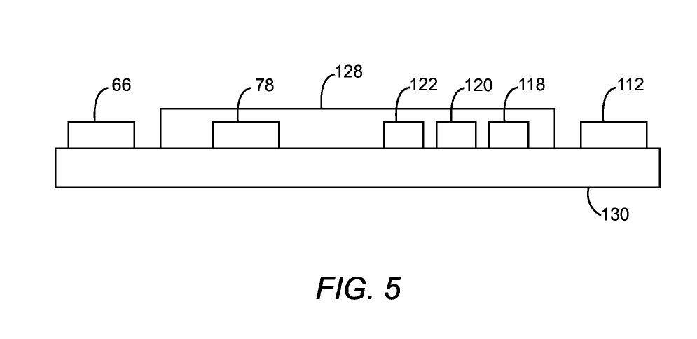

FIG. 5 shows a cross-sectional view of the adjustable impedance tuning circuitry 12 shown in FIG. 4 according to one embodiment of the present disclosure. As shown in FIG. 5, the adjustable impedance tuning circuitry 12 includes the adjustable impedance tuning PCB 130, the adjustable impedance tuning semiconductor die 128, the first shunt tuning inductor 66, the second shunt ESD inductor 78, the sixth switchable capacitor 122, the fifth switchable capacitor 120, the third fixed capacitor 118, and the second fixed inductor 76. Each one of the first shunt tuning inductor 66, the second shunt ESD inductor 78, the sixth switchable capacitor 122, the fifth switchable capacitor 120, the third fixed capacitor 118, and the second fixed inductor 76 are mounted onto the adjustable impedance tuning circuitry PCB 130 separately from the adjustable impedance tuning semiconductor die 128, and placed in electrical communication with the adjustable impedance tuning semiconductor die 128 via one or more conductive traces (not shown). Additional components of the adjustable impedance tuning circuitry 12 such as the first shunt ESD inductor 64, the first shunt tuning capacitor 68, the first series tuning inductor 70, and the second shunt tuning capacitor 72 are similarly mounted to the adjustable impedance tuning PCB 130, but are obscured from view in FIG. 5.

The adjustable impedance tuning semiconductor die 128 is similarly mounted to the adjustable impedance tuning PCB 130. By integrating the switching components of the adjustable tuning components onto the adjustable impedance tuning semiconductor die 128 along with the control circuitry 16, interference within the adjustable impedance tuning circuitry 12 is minimized, thereby allowing for stable operation of the circuitry over a wide bandwidth. Further, by externally mounting the inductive and capacitive components, the design of the adjustable impedance tuning circuitry 12 remains flexible, and fabrication costs are reduced.

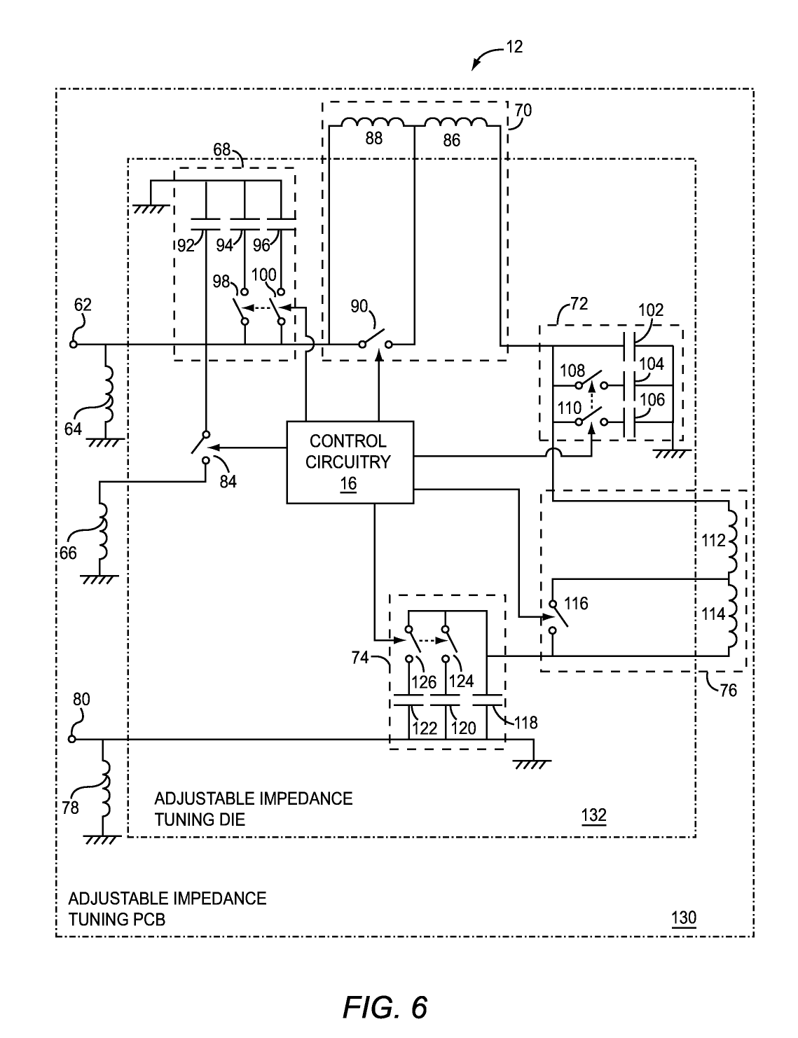

FIG. 6 shows a schematic representation of the adjustable impedance tuning circuitry 12 shown in FIG. 3 including further details of the layout of the adjustable impedance tuning circuitry 12 according to an additional embodiment of the present disclosure. As shown in FIG. 6, the adjustable impedance tuning circuitry 12 includes an adjustable impedance tuning semiconductor die 132 mounted on top of an adjustable impedance tuning PCB 134. As discussed above, each one of the first shunt tuning inductor 66, the first shunt tuning capacitor 68, the first series tuning inductor 70, the second shunt tuning capacitor 72, the second series tuning inductor 76, and the third shunt tuning capacitor 74 may be associated with one or more switches adapted to selectively alter the impedance of the aforementioned components.

According to one embodiment of the present disclosure, each one of the switches associated with the first shunt tuning inductor 66, the first shunt tuning capacitor 68, the first series tuning inductor 70, the second shunt tuning capacitor 72, the second series tuning inductor 76, and the third shunt tuning capacitor 74 are integrated onto a single semiconductor die, such as the adjustable impedance tuning semiconductor die 132 shown in FIG. 6. According to this embodiment, the switches associated with the first shunt tuning inductor 66, the first shunt tuning capacitor 68, the first series tuning inductor 70, the second shunt tuning capacitor 72, the second series tuning inductor 76, and the third shunt tuning capacitor 74 are integrated onto the adjustable impedance tuning semiconductor die 132 together with the capacitors associated with the first shunt tuning capacitor 68, the second shunt tuning capacitor 72, and the third shunt tuning capacitor 74. The inductors associated with the first shunt ESD inductor 64, the first shunt tuning inductor 66, the first series tuning inductor 70, the second series tuning inductor 76, and the second shunt ESD inductor 78 are not integrated onto the adjustable impedance tuning semiconductor die 132, and instead are mounted on the adjustable impedance tuning PCB 134 on which the adjustable impedance tuning semiconductor die 132 is mounted. By integrating the switches associated with the first shunt tuning inductor 66, the first shunt tuning capacitor 68, the first series tuning inductor 70, the second shunt tuning capacitor 72, the second series tuning inductor 76, and the third shunt tuning capacitor 74, as well as the capacitors associated with the first shunt tuning capacitor 68, the second shunt tuning capacitor 72, and the third shunt tuning capacitor 74 onto the adjustable impedance tuning semiconductor die 132, interference within the adjustable impedance tuning circuitry 12 is reduced, thereby allowing for stable operation of the circuitry over a wide bandwidth.

According to one embodiment of the present disclosure, the switches associated with the first shunt tuning inductor 66, the first shunt tuning capacitor 68, the first series tuning inductor 70, the second shunt tuning capacitor 72, the second series tuning inductor 76, and the third shunt tuning capacitor 74 are integrated onto the adjustable impedance tuning semiconductor die 132 using a CMOS process. By using a CMOS process to integrate the switches associated with the first shunt tuning inductor 66, the first shunt tuning capacitor 68, the first series tuning inductor 70, the second shunt tuning capacitor 72, the second series tuning inductor 76, and the third shunt tuning capacitor 74 onto the adjustable impedance tuning semiconductor die 132, the cost of the adjustable impedance tuning circuitry 12 is minimized while maintaining a high level of performance.

According to one embodiment of the present disclosure, the switches associated with the first shunt tuning inductor 66, the first shunt tuning capacitor 68, the first series tuning inductor 70, the second shunt tuning capacitor 72, the second series tuning inductor 76, and the third shunt tuning capacitor 74, as well as the capacitors associated with the first shunt tuning capacitor 68, the second shunt tuning capacitor 72, and the third shunt tuning capacitor 74 are integrated onto a single semiconductor die together with the control circuitry 16, as shown in FIG. 6. By integrating the switches associated with the first shunt tuning inductor 66, the first shunt tuning capacitor 68, the first series tuning inductor 70, the second shunt tuning capacitor 72, the second series tuning inductor 76, and the third shunt tuning capacitor 74, the capacitors associated with the first shunt tuning capacitor 68, the second shunt tuning capacitor 72, and the third shunt tuning capacitor 74, and the control circuitry 16 onto the adjustable impedance tuning semiconductor die 132, interference within the adjustable impedance tuning circuitry 12 is further reduced, thereby allowing for stable operation of the circuitry over a wide bandwidth.

The control circuitry 16 is coupled to each one of the switches on the adjustable impedance matching semiconductor die 132, and is adapted to adjust the state of one or more switches in order to match an impedance present at the first impedance matching terminal 62 to an impedance at the second impedance matching terminal 80.

Those skilled in the art will recognize improvements and modifications to the preferred embodiments of the present disclosure. All such improvements and modifications are considered within the scope of the concepts disclosed herein and the claims that follow.

What is claimed is:

1. Adjustable impedance tuning circuitry comprising:
a first impedance matching terminal and a second impedance matching terminal; and
a plurality of passive components adapted to match an impedance at the first impedance matching terminal to an impedance at the second impedance matching terminal, wherein:
the plurality of passive components includes one or more tunable components;
the one or more tunable components include one or more tuning switches adapted to alter an impedance of the one or more tunable components; and
each of the one or more tuning switches are integrated onto a single semiconductor die.

2. The adjustable impedance tuning circuitry of claim 1 further comprising control circuitry coupled to the one or more tunable components and adapted to adjust the impedance of the one or more tunable components in order to match the impedance at the first impedance matching terminal to the impedance at the second impedance matching terminal.

3. The adjustable impedance tuning circuitry of claim 2 wherein the control circuitry is integrated onto the single semiconductor die with each of the one or more tuning switches from the one or more tunable components.

4. The adjustable impedance tuning circuitry of claim 1 wherein each of the one or more tuning switches are integrated onto the single semiconductor die using a complementary metal oxide semiconductor (CMOS) process.

5. The adjustable impedance tuning circuitry of claim 1 wherein the single semiconductor die is mounted onto a printed circuit board.

6. The adjustable impedance tuning circuitry of claim 5 wherein:
the plurality of passive components including the one or more tunable components are mounted onto the printed circuit board; and
the one or more tunable components are coupled to the one or more tuning switches integrated onto the single semiconductor die.

7. The adjustable impedance tuning circuitry of claim 5 wherein:
the one or more tunable components include one or more tunable capacitors and one or more tunable inductors; and
the one or more tunable capacitors are integrated onto the single semiconductor die with the one or more tuning switches.

8. The adjustable impedance tuning circuitry of claim 7 wherein a remainder of the plurality of passive components are mounted onto the printed circuit board.

9. The adjustable impedance tuning circuitry of claim 8 further including control circuitry coupled to the one or more tunable components and adapted to adjust the impedance of the one or more tunable components in order to match the impedance at the first impedance matching terminal to the impedance at the second impedance matching terminal.

10. The adjustable impedance tuning circuitry of claim 9 wherein the control circuitry is integrated onto the single semiconductor die with each of the one or more tuning switches.

11. The adjustable impedance tuning circuitry of claim 1 wherein the plurality of passive components comprises:
a pi low pass filter network including:
a first shunt tuning capacitor coupled between the first impedance matching terminal and ground;
a first series tuning inductor coupled between the first impedance matching terminal and a third terminal;
a second shunt tuning capacitor coupled between the third terminal and ground;
a second series tuning inductor coupled between the third terminal and the second impedance matching terminal; and
a third shunt tuning capacitor coupled between the second impedance matching terminal and ground;
a first shunt electrostatic discharge (ESD) inductor coupled between the first impedance matching terminal and ground; and
a first shunt tuning inductor coupled between the first impedance matching terminal and ground.

12. The adjustable impedance tuning circuitry of claim 11 wherein:
the first shunt tuning inductor is coupled to the first impedance matching terminal through a first shunt inductor switch; and
the first shunt inductor switch is adapted to selectively couple the first shunt tuning inductor to the first impedance matching terminal.

13. The adjustable impedance tuning circuitry of claim 11 wherein each of the first shunt tuning capacitor, the first series tuning inductor, the second shunt tuning capacitor, the second series tuning inductor, and the third shunt tuning capacitor have an adjustable impedance.

14. The adjustable impedance tuning circuitry of claim 11 wherein each of the first shunt tuning capacitor, the second shunt tuning capacitor, and the third shunt tuning capacitor comprise a programmable array of capacitors.

15. The adjustable impedance tuning circuitry of claim 14 wherein each one of the programmable array of capacitors comprises:
one or more switched capacitors comprising:
a switchable capacitor coupled in series with a capacitor tuning switch; and
a fixed capacitor coupled in parallel with the one or more switched capacitors.

16. The adjustable impedance tuning circuitry of claim 11 wherein each of the first series tuning inductor and the second series tuning inductor comprises:
one or more switched inductors comprising:
a switchable inductor coupled in parallel with an inductor tuning switch; and
a fixed inductor coupled in series with the one or more switched inductors.

17. The adjustable impedance tuning circuitry of claim 11 further comprising a second shunt ESD inductor coupled between the second impedance matching terminal and ground.

18. The adjustable impedance tuning circuitry of claim 17 wherein the first shunt ESD inductor and the second shunt ESD inductor are adapted to divert ESD signals of a certain threshold away from the adjustable impedance tuning circuitry to ground.

19. The adjustable impedance tuning circuitry of claim 18 wherein the first shunt ESD inductor and the second shunt ESD inductor are further adapted to provide a fixed impedance transformation at the first impedance matching terminal and the second impedance matching terminal.

20. The adjustable impedance matching circuitry of claim 1 wherein the adjustable impedance matching circuitry is adapted to operate about a low band frequency range of 698 megahertz (MHz) to 960 MHz.

21. The adjustable impedance matching circuitry of claim 1 wherein the adjustable impedance matching circuitry is adapted to operate about a high band frequency range of 1710 megahertz (MHz) to 2700 MHz.

22. Mobile terminal front end circuitry comprising:
adjustable impedance tuning circuitry comprising:
a first impedance matching terminal and a second impedance matching terminal; and
a plurality of passive components adapted to match an impedance at the first impedance matching terminal to an impedance at the second impedance matching terminal, wherein:
the plurality of passive components includes one or more tunable components;
the one or more tunable components include one or more tuning switches adapted to alter an impedance of the tunable components; and
each of the one or more tuning switches are integrated onto a single semiconductor die;
an antenna coupled to the second impedance matching terminal of the adjustable impedance tuning circuitry;
a diplexer coupled to the first impedance matching terminal;
antenna switching circuitry coupled to the diplexer, such that the diplexer is coupled between the antenna switching circuitry and the adjustable impedance tuning circuitry;
transceiver circuitry;
low-noise amplifier circuitry coupled between the transceiver circuitry and the antenna switching circuitry;
power amplifier circuitry coupled to the antenna switching circuitry; and
a modulator coupled between the transceiver circuitry and the power amplifier circuitry.

23. Mobile terminal front end circuitry comprising:
adjustable impedance tuning circuitry comprising:
a first impedance matching terminal and a second impedance matching terminal; and
a plurality of passive components adapted to match an impedance at the first impedance matching terminal to an impedance at the second impedance matching terminal, wherein:
the plurality of passive components includes one or more tunable components;
the one or more tunable components include one or more tuning switches adapted to alter an impedance of the tunable components; and
each of the one or more tuning switches are integrated onto a single semiconductor die;
an antenna coupled to the second impedance matching terminal of the adjustable impedance tuning circuitry;
antenna switching circuitry coupled to first impedance matching terminal;
transceiver circuitry;
low-noise amplifier circuitry coupled between the transceiver circuitry and the antenna switching circuitry;
power amplifier circuitry coupled to the antenna switching circuitry; and
a modulator coupled between the transceiver circuitry and the power amplifier circuitry.
